(19) United States
(12) Patent Application Publication
(10) Pub. No.: US 2024/0145375 A1
(43) Pub. Date: May 2, 2024

(54) SEMICONDUCTOR PACKAGE AND METHOD FOR MANUFACTURING THE SAME

(71) Applicant: Samsung Electronics Co., Ltd., Suwon-si (KR)

(72) Inventors: Hyeonjeong HWANG, Suwon-si (KR); Dongkyu KIM, Suwon-si (KR); Inhyung SONG, Suwon-si (KR)

(73) Assignee: Samsung Electronics Co., Ltd., Suwon-si (KR)

(21) Appl. No.: 18/311,405

(22) Filed: May 3, 2023

(30) Foreign Application Priority Data
Oct. 26, 2022 (KR) 10-2022-0139609

(51) Int. Cl. H01L 23/498; H01L 21/02; H01L 21/768; H01L 23/00; H01L 25/10

(52) U.S. Cl. CPC H01L 23/49894; H01L 21/02164; H01L 21/76814; H01L 21/76843; H01L 21/76873; H01L 23/49838; H01L 24/13; H01L 24/16; H01L 24/29; H01L 24/32; H01L 24/73; H01L 24/81; H01L 24/83; H01L 25/105; H01L 2224/13147; H01L 2224/16227; H01L 2224/29187; H01L 2224/32225; H01L 2224/73204; H01L 2224/81895; H01L 2224/83896; H01L 2225/1041; H01L 2924/182

(57) ABSTRACT

A semiconductor package includes an interposer including a first redistribution layer and a second redistribution layer that is on the first redistribution layer and is electrically coupled to the first redistribution layer; and a semiconductor chip on the interposer. The first redistribution layer includes a first organic insulating layer and a plurality of first conductors in the first organic insulating layer. The second redistribution layer includes a second organic insulating layer, a first silicon insulating layer on the second organic insulating layer, and a plurality of second conductors penetrating through both the second organic insulating layer and the first silicon insulating layer. The semiconductor chip includes a second silicon insulating layer and a plurality of third conductors in the second silicon insulating layer. The second conductors are directly bonded to separate, respective third conductors and the first silicon insulating layer is directly bonded to the second silicon insulating layer.

### CROSS-REFERENCE TO RELATED APPLICATION

This application claims priority to and the benefit of Korean Patent Application No. 10-2022-0139609 filed in the Korean Intellectual Property Office on Oct. 26, 2022, the entire contents of which are incorporated herein by reference.

### BACKGROUND

### (a) Field

The present inventive concepts relate to semiconductor packages and methods for manufacturing (fabricating) the same.

### (b) Description of the Related Art

Silicon has a similar thermal expansion coefficient to that of a semiconductor chip so that it has high thermal stability in relation to the semiconductor chip, and has material properties that are easy to apply to a process of forming semiconductor fine wiring and vias. By using properties of a silicon material, a silicon interposer disposed between the wiring board and the semiconductor and made of the same material as that of the semiconductor chip, so that a stress caused by a difference in a thermal expansion coefficient between a wiring board and the semiconductor chip is relieved, and an electrical connection between the wiring board and the semiconductor chip is more efficient. Such a silicon interposer is well known in a field of a semiconductor package.

the silicon interposer may use a hybrid bonding process during bonding to a semiconductor chip. The hybrid bonding process may be performed by two types of bonding (i.e., direct bonding of metal to metal and direct bonding of non-metal to non-metal). Therefore, if the silicon interposer is used for the direct bonding, a multi-stage stack may be formed without a use of a solder ball. Based on the advantage, the silicon interposer is utilized as one of the important components in f 2.5D and 3D integrated circuit chips.

However, a price of the silicon, the material of the silicon interposer, is higher than that of another material. Therefore, when a complex circuit structure needs to be designed or a size of a substrate increases so that use of the silicon material increases, increase in cost due to the use of the silicon material is very high compared with the other material.

On the other hand, in the case of an organic interposer, material and process costs are lower than those of the silicon interposer, and it is easy to use a conventional process during a manufacturing process. However, since the organic interposer uses an organic material for a dielectric layer, it is difficult to apply the hybrid bonding process in a bonding process between the organic interposer and the semiconductor chip, and a solder ball should be used.

Therefore, it is necessary to develop a new package technology capable of applying the hybrid bonding process while using the organic interposer when bonding between semiconductor devices is performed.

### SUMMARY

Some example embodiments provide a semiconductor package and/or a method for manufacturing the semiconductor package in which an organic insulating layer, an oxide layer above the organic insulating layer, and conductors penetrating the organic insulating layer and the oxide layer are formed in a redistribution layer of an organic interposer so that a hybrid bonding process may be applied to the organic interposer.

A semiconductor package according to some example embodiments may include: an interposer including a first redistribution layer and a second redistribution layer that is on the first redistribution layer and is electrically coupled to the first redistribution layer; and a semiconductor chip on the interposer. The first redistribution layer may include a first organic insulating layer and a plurality of first conductors in the first organic insulating layer. The second redistribution layer may include a second organic insulating layer, a first silicon insulating layer on the second organic insulating layer, and a plurality of second conductors penetrating through both of the second organic insulating layer and the first silicon insulating layer. The semiconductor chip may include a second silicon insulating layer and a plurality of third conductors in the second silicon insulating layer. Each second conductor of the plurality of second conductors may be directly bonded to a separate, respective third conductor of the plurality of third conductors, and the first silicon insulating layer may be directly bonded to the second silicon insulating layer.

A level of an uppermost surface of plurality of the second conductors and a level of an uppermost surface of the first silicon insulating layer may be substantially a same level.

Both of the first silicon insulating layer and the second silicon insulating layer may include a silicon oxide.

Both of the plurality of second conductors and the plurality of third conductors may include copper (Cu).

The interposer may include an organic interposer.

Each of the first organic insulating layer and the second organic insulating layer may include a photo imageable dielectric (PID).

The second redistribution layer may further include barrier metal layers. The barrier metal layers may be between the plurality of second conductors and a stack including both of the second organic insulating layer and the first silicon insulating layer.

Each barrier metal layer of the barrier metal layers may include titanium (Ti).

A semiconductor package according to some example embodiments may include: an interposer that includes a first redistribution layer and a second redistribution layer on the first redistribution layer; and a semiconductor chip on the interposer. The first redistribution layer may include: a first organic insulator; and a plurality of first conductors that includes redistribution lines and redistribution vias in the first organic insulating layer. The second redistribution layer may include: a second organic insulator layer; a first silicon insulating layer on the second organic insulating layer; a plurality of second conductors that penetrate through both of the second organic insulating layer and the first silicon insulating layer, the plurality of second conductors electrically coupling the first redistribution layer and the semiconductor chip, wherein a level of an uppermost surface of the plurality of second conductors and a level of an uppermost surface of the first silicon insulating layer may be substantially a same level; and barrier metal layers that are interposed at interfaces between the plurality of second conductors and a stack including the second organic insulating layer and the first silicon insulating layer. The semiconductor chip may include a plurality of third conductors and a second silicon insulating layer. Each second conductor of the plurality of second conductors may be directly bonded to a separate, respective third conductor of the plurality of third conductors and the first silicon insulating layer may be directly bonded to the second silicon insulating layer.

The first silicon insulating layer may have a thickness of about 100 nm to about 1000 nm.

Each barrier metal layer of the barrier metal layers may have a thickness of about 10 nm to about 300 nm.

A sum of a pitch of a cross-section of one second conductor of the plurality of second conductors, a pitch of a cross-section of the barrier metal layers on sidewalls of the one second conductor, and a pitch of a cross-section of the stack may be about 1 μm to about 380 μm.

A method for manufacturing a semiconductor package according to some example embodiments may include: forming a first silicon insulating layer on a first seed metal layer; forming an organic insulating layer including a plurality of openings to expose the first silicon insulating layer; removing the exposed first silicon insulating layer to expose the first seed metal layer; forming a barrier metal layer on an upper surface and sidewalls of the organic insulating layer; forming a second seed metal layer on both of the first seed metal layer and the barrier metal layer; forming a plurality of first conductors on the second seed metal layer in the plurality of openings of the organic insulating layer; removing both of the barrier metal layer and the second seed metal layer above the upper surface of the organic insulating layer; forming a redistribution layer on both of the upper surface of the organic insulating layer and an upper surface of the first conductors; removing the first seed metal layer to expose the plurality of first conductors and the first silicon insulating layer; and bonding each first conductor of the plurality of first conductors to a separate, respective second conductor of a plurality of second conductors of a semiconductor chip, and bonding the first silicon insulating layer to a second silicon insulating layer of the semiconductor chip.

The removing of the exposed first silicon insulating layer may include removing scum of the organic insulating layer.

The first seed metal layer and the barrier metal layer may include titanium (Ti). The second seed metal layer and the plurality of first conductors may include copper (Cu). The second seed metal layer may have a thickness of about 30 nm to 1 about 500 nm.

The forming of the second seed metal layer may include performing sputtering or electroless plating.

The forming of the plurality of first conductors may include performing electroplating.

In the removing of the first seed metal layer, an uppermost surface of the plurality of first conductors and an uppermost surface of the first silicon insulating layer may be at substantially a same level without performing a chemical mechanical polishing (CMP) process.

The bonding each of the plurality of first conductors to each of the plurality of second conductors of the semiconductor chip may include annealing at a temperature of about 100° C. to about 500° C. and a pressure of less than 30 MPa.

Before the forming of the plurality of first conductors, a photoresist may be formed on the second seed metal layer above the upper surface of the organic insulating layer.

According to some example embodiments, the hybrid bonding process may be applied to the organic interposer by forming an organic insulating layer, a silicon insulating layer above the organic insulating layer, and conductors penetrating the organic insulating layer and the silicon insulating layer in the redistribution layer of the organic interposer. Thus, it is possible to broaden a range of use of the organic interposer.

According to some example embodiments, since an upper surface of the silicon insulating layer and an upper surface of the conductors are formed to have substantially the same level in a manufacturing process of the organic interposer, a chemical mechanical polishing (CMP) process that may be performed before hybrid bonding may be omitted.

According to some example embodiments, only a process of forming the silicon insulating layer and a process of etching the silicon insulating layer are added to an organic interposer in a conventional chip last organic interposer manufacturing process so that the organic interposer to which the hybrid bonding process may be applied is provided.

According to some example embodiments, an oxidative chemical reaction that may occur between the conductors and a stack of the organic insulating layer and the silicon insulating layer may be prevented and chemical stability between structures may be increased by interposing the barrier metal layer at interfaces between the conductors and the stack of the organic insulating layer and the silicon insulating layer.

### BRIEF DESCRIPTION OF THE DRAWINGS

FIG. 1 is a cross-sectional view illustrating hybrid bonding between a semiconductor chip and a silicon interposer according to some example embodiments.

FIG. 2 is a cross-sectional view illustrating a semiconductor package according to some example embodiments in which a semiconductor chip having a silicon insulating layer and conductors and an organic interposer having a silicon insulating layer and conductors that are the same material as that of the semiconductor chip on an upper redistribution layer are hybrid-bonded.

FIG. 3 is a cross-sectional view enlarging an area A of the organic interposer in the cross-sectional view of FIG. 2 according to some example embodiments.

FIG. 4 is a cross-sectional view illustrating a step of forming a first seed metal layer as one of the steps of a method for manufacturing the semiconductor package according to some example embodiments.

FIG. 5 is a cross-sectional view illustrating a step of forming a first silicon insulating layer as one of the steps of a method for manufacturing the semiconductor package according to some example embodiments.

FIG. 6 is a cross-sectional view illustrating a step of forming a patterned second organic insulating layer as one of the steps of a method for manufacturing the semiconductor package according to some example embodiments.

FIG. 7 is a cross-sectional view illustrating a step of removing an exposed first silicon insulating layer as one of the steps of a method for manufacturing the semiconductor package according to some example embodiments.

FIG. 8 is a cross-sectional view illustrating a step of forming a barrier metal layer and a second seed metal layer as one of the steps of a method for manufacturing the semiconductor package according to some example embodiments.

FIG. 9 is a cross-sectional view illustrating a step of forming a patterned photoresist as one of the steps of a method for manufacturing the semiconductor package according to some example embodiments.

FIG. 10 is a cross-sectional view illustrating a step of forming conductors at openings of a photoresist as one of the steps of a method for manufacturing the semiconductor package according to some example embodiments.

FIG. 11 is a cross-sectional view illustrating a step of removing the photoresist as one of the steps of a method for manufacturing the semiconductor package according to some example embodiments.

FIG. 12 is a cross-sectional view illustrating a step of removing the barrier metal layer and the second seed metal layer as one of the steps of a method for manufacturing the semiconductor package according to some example embodiments.

FIG. 13 is a cross-sectional view illustrating a step of performing a chemical mechanical polishing (CMP) as one of the steps of a method for manufacturing the semiconductor package according to some example embodiments.

FIG. 14 is a cross-sectional view illustrating a step of forming the redistribution layer of the organic interposer as one of the steps of a method for manufacturing the semiconductor package according to some example embodiments.

FIG. 15 is a cross-sectional view illustrating a step of removing a carrier as one of the steps of a method for manufacturing the semiconductor package according to some example embodiments.

FIG. 16 is a cross-sectional view illustrating a step of removing the first seed metal layer as one of the steps of a method for manufacturing the semiconductor package according to some example embodiments.

FIG. 17 is a cross-sectional view illustrating a step of hybrid-bonding the organic interposer and a semiconductor chip as one of the steps of a method for manufacturing the semiconductor package according to some example embodiments.

### DETAILED DESCRIPTION

The present inventive concepts will be described more fully hereinafter with reference to the accompanying drawings, in which some example embodiments of the inventive concepts are shown. As those skilled in the art would realize, the described example embodiments may be modified in various different ways, all without departing from the spirit or scope of the present inventive concepts.

In order to clearly describe the present inventive concepts, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present inventive concepts is not necessarily limited to those illustrated in the drawings.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%)).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

Hereinafter, a semiconductor package according to some example embodiments will be described with reference to the drawings.

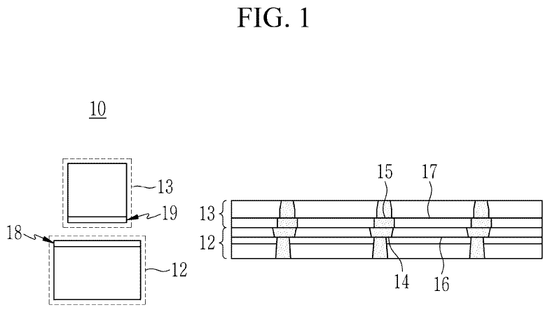

FIG. 1 is a cross-sectional view illustrating hybrid bonding between a silicon interposer 12 and a semiconductor chip 13 according to some example embodiments.

Referring to FIG. 1, in some example embodiments a semiconductor package 10 includes the silicon interposer 12 and the semiconductor chip 13 bonded on the silicon interposer 12. The silicon interposer 12 electrically connects semiconductor devices and a wiring board, and is formed by forming a via hole at a silicon substrate and filling the via hole with a conductive material. The silicon interposer 12 may include a through copper via 14 and a silicon oxide layer 16.

A right side view of FIG. 1 is a view enlarging a bonding interface between the silicon interposer 12 and the semiconductor chip 13. In some example embodiments, the silicon interposer 12 and the semiconductor chip 13 are bonded by hybrid bonding. In some example embodiments, the through copper via 14 exposed at an upper surface 18 of the silicon interposer 12 is directly bonded to a copper pad 15 of a lower surface 19 of the semiconductor chip 13 by metal-metal hybrid bonding. In some example embodiments, a metallic bond is formed by heat and pressure at an interface between the through copper via 14 and the copper pad 15. In some example embodiments, the silicon oxide layer 16 exposed at an upper surface 18 of the silicon interposer 12 is directly bonded to a silicon oxide pad 17 of a lower surface 19 of the semiconductor chip 13 by non-metal-non-metal hybrid bonding. In some example embodiments, a covalent bond is formed by heat and pressure at an interface between the silicon oxide layer 16 and the silicon oxide pad 17.

If the silicon interposer capable of hybrid bonding is used, a multi-stage stack may be formed without a use of a solder ball, and wiring may be performed with a very small bonding pitch (about 10 μm). However, a price of a silicon, the material of the silicon interposer, is higher than that of other materials that could be included in the interposer. Therefore, when a complex circuit structure needs to be designed or a size of a substrate increases so that use of the silicon material increases, increase in cost of the interposer due to the use of the silicon material is very high compared with other materials.

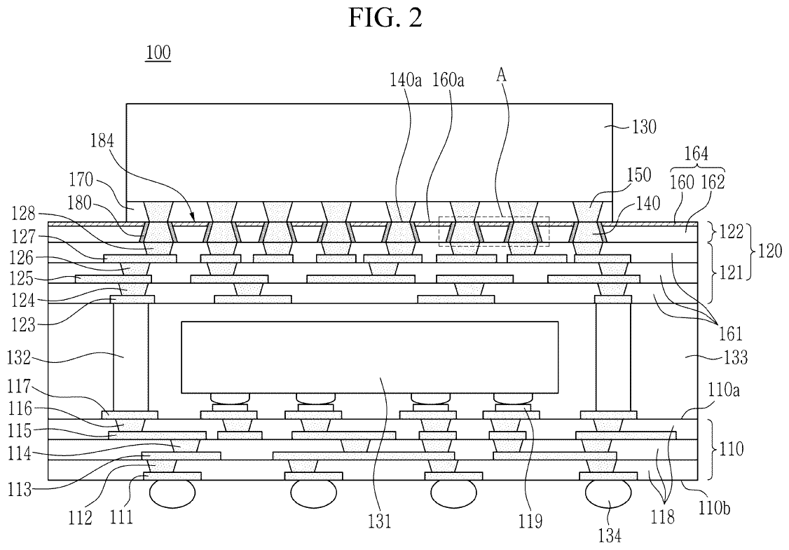

FIG. 2 is a cross-sectional view illustrating a semiconductor package 100 in which a first semiconductor chip 130 having a silicon insulating layer 170 and a plurality of third conductors 150 and an organic interposer 120 having a silicon insulating layer 160 and a plurality of second conductors 140 are hybrid-bonded according to some example embodiments. The second conductors 140 of the organic interposer 120 are made of (e.g., comprise) the same material as the third conductors 150 of the first semiconductor chip 130, and the silicon insulating layer 160 of the organic interposer 120 is made of the same material as the silicon insulating layer 170 of the first semiconductor chip 130.

Referring to FIG. 2, the semiconductor package 100 includes a front side redistribution layer (FRDL) 110. The front side redistribution layer 110 includes front side redistribution lines 111, 113, and 115, front side redistribution vias 112, 114, and 116, and an insulating layer 118 for molding the front side redistribution lines 111, 113, and 115 and the front side redistribution vias 112, 114, and 116 therein. The insulating layer 118 may protect the front side redistribution lines 111, 113, and 115 and the front side redistribution vias 112, 114, and 116 from an external impact. In some example embodiments, each of the front side redistribution lines 111, 113, and 115 and the front side redistribution vias 112, 114, and 116 may be formed of at least one of: copper, nickel, aluminum, titanium, or an alloy of copper, nickel, aluminum, and/or titanium. In some example embodiments, the insulating layer 118 may include at least one of: epoxy resin, polybenzobisoxazole (PBO), benzocyclobutene (BCB), polyimide, or polyimide derivatives. In some example embodiments, the insulating layer 118 may be formed of an inorganic dielectric material such as a silicon nitride and a silicon oxide.

In some example embodiments, including some example embodiments including the front side redistribution layer 110 of FIG. 2, the front side redistribution lines 111, 113, and 115, the front side redistribution vias 112, 114, and 116, and the insulating layer 118 are shown, but the number (e.g., quantity), disposition, or arrangement of the front side redistribution vias, the front side redistribution lines, and the insulating layer is not limited thereto, and the front side redistribution layer 110 may include more or fewer front side redistribution vias, front side redistribution lines, and insulating layers, a different disposition, or a different arrangement of front side redistribution vias, front side redistribution lines, and an insulating layer.

An uppermost front side redistribution via 116 of the front side redistribution layer 110 may be bonded to a through via 132 and a conductive connection member 119 of a second semiconductor chip 131 through respective conductive connection pads 117, and may be electrically coupled to the organic interposer 120 and the second semiconductor chip 131. A lowermost front side redistribution line 111 of the front side redistribution layer 110 may be bonded to a solder ball 134 to be electrically coupled to an external device.

The semiconductor package 100 includes the second semiconductor chip 131. The second semiconductor chip 131 is bonded to and electrically coupled to the front side redistribution layer 110 by the conductive connection member 119. The second semiconductor chip 131 may be supported by the front side redistribution layer 110. Although one second semiconductor chip 131 is illustrated in FIG. 2, a plurality of semiconductor chips may be included in the semiconductor package 100. In some example embodiments, the second semiconductor chip 131 may be a system on chip (SOC).

The semiconductor package 100 includes the through via 132. The through via 132 is disposed on the front side redistribution layer 110 and electrically couples the front side redistribution layer 110 to the organic interposer 120. In some example embodiments, the through via 132 may include at least one of copper, aluminum, tungsten, nickel, gold, tin, titanium, or an alloy of copper, aluminum, tungsten, nickel, gold, tin, and/or titanium.

The semiconductor package 100 includes a molding material 133. The molding material 133 molds the second semiconductor chip 131, the through via 132, and the front side redistribution layer 110 therein. The molding material 133 may surround the second semiconductor chip 131. The molding material 133 may be configured to protect and fix the second semiconductor chip 131. In some example embodiments, the molding material 133 may be a molding compound, a molding underfill, an epoxy, and/or a resin.

The semiconductor package 100 includes the organic interposer 120. The organic interposer 120 includes a first redistribution layer 121 and a second redistribution layer 122.

The first redistribution layer 121 corresponds to a redistribution layer of a conventional organic interposer. The first redistribution layer 121 includes redistribution lines 123, 125, and 127, the redistribution vias 124, 126, and 128, and a first organic insulating layer 161 for molding the redistribution lines 123, 125, and 127 and the redistribution vias 124, 126, and 128 therein. In some example embodiments, the redistribution lines 123, 125, and 127 and the redistribution vias 124, 126, and 128 may comprise first conductors in (e.g., within) the first organic insulating layer 161. The first organic insulating layer 161 may protect the redistribution lines 123, 125, and 127 and the redistribution vias 124, 126, and 128 from an external impact. In some example embodiments, the redistribution lines 123, 125, and 127 and the redistribution vias 124, 126, and 128 may be formed of at least one of copper, nickel, aluminum, titanium, or an alloy of copper, nickel, aluminum, and/or titanium.

The first organic insulating layer 161 may be a photosensitive polymer layer. A photosensitive polymer is a material capable of forming a fine pattern by applying a photolithography process. The photosensitive polymer may include a photo imageable dielectric (PID) material. In some example embodiments, the PID may include a polyimide-based photosensitive polymer, a novolac-based photosensitive polymer, polybenzoxazole, a silicone-based polymer, an acrylate-based polymer, or an epoxy-based polymer. The PID has an advantage of relatively low material cost and ease of manufacture compared with other materials used for insulating layers.

In some example embodiments, including the first redistribution layer 121 of FIG. 2, the redistribution lines 123, 125, and 127, the redistribution vias 124, 126, and 128, and the first organic insulating layer 161 are illustrated, but the number (e.g., quantity), a disposition, or an arrangement of the redistribution vias, the redistribution lines, and the first organic insulating layer is not limited thereto, and the first redistribution layer 121 may include more or fewer redistribution vias, redistribution lines, and first organic insulating layers, a different disposition, or a different arrangement of redistribution vias, redistribution lines, and a first organic insulating layer.

The second redistribution layer 122 is on the first redistribution layer 121 and is electrically coupled to the first redistribution layer 121. The second redistribution layer 122 includes a second organic insulating layer 162, the silicon insulating layer 160, the second conductors 140, and barrier metal layers 180.

Like the first organic insulating layer 161, the second organic insulating layer 162 may be a photosensitive polymer layer. The second organic insulating layer 162 may include a photo imageable dielectric (PID) material as a photosensitive polymer. In some example embodiments, the PID may include a polyimide-based photosensitive polymer, a novolac-based photosensitive polymer, polybenzoxazole, a silicone-based polymer, an acrylate-based polymer, or an epoxy-based polymer.

The silicon insulating layer 160 is positioned on the second organic insulating layer 162. In some example embodiments, the silicon insulating layer 160 may include a silicon oxide. In some example embodiments, the silicon insulating layer 160 may include SiO₂. In some example embodiments, the silicon insulating layer 160 may be a silicon nitride, a silicon oxynitride, or another suitable dielectric material. The silicon insulating layer 160 may be referred to interchangeably herein as a first silicon insulating layer.

Each of the second conductors 140 is formed to penetrate both the second organic insulating layer 162 and the silicon insulating layer 160 on the second organic insulating layer 162. An upper surface 140a of the second conductors 140 and an upper surface 160a of the silicon insulating layer 160 may have substantially the same level (e.g., a same or substantially same level). For example, the upper surface 140a of the second conductors 140 and an upper surface 160a of the silicon insulating layer 160 may be coplanar or substantially coplanar. As a result, a level of an uppermost surface of each of the second conductors 140 (upper surface 140a) and a level of an uppermost surface of the silicon insulating layer 160 may be substantially a same level (e.g., upper surfaces 140a and 160a may be coplanar or substantially coplanar). In some example embodiments, the second conductors 140 may include copper. In some example embodiments, the second conductors 140 may be a metallic material to which hybrid bonding may be applied.

In the present specification, the term ‘level’, ‘vertical level’, ‘depth’, ‘height’, or the like may mean a vertical height (e.g., vertical distance in the third direction Z) measured from a reference location (e.g., the first surface 110a and/or the second surface 110b of the front side redistribution layer 110) in a direction perpendicular to the plane or surface at the reference location (e.g., a vertical direction perpendicular to the first surface 110a and/or the second surface 110b of the front side redistribution layer 110). For example, where elements (e.g., surfaces) are described herein to be at different levels, it will be understood that the respective distances of the elements from the reference location (e.g., the first surface 110a and/or the second surface 110b of the front side redistribution layer 110) in the vertical direction may be different from each other. In another example, where a level of a first element is described herein to be between at least two other elements, it will be understood that the first element is between the at least two other elements in the vertical direction. In another example, where a level of a first element is described herein to be lower, less, or smaller than a level of a second element, it will be understood that the distance of the first element from the reference location (e.g., the first surface 110a and/or the second surface 110b of the front side redistribution layer 110) in the vertical direction may be smaller than the distance of the second element from the reference location in the vertical direction. In another example, where a level of a first element is described herein to be higher, larger, or greater than a level of a second element, it will be understood that the distance of the first element from the reference location (e.g., the first surface 110a and/or the second surface 110b of the front side redistribution layer 110) in the vertical direction may be greater than the distance of the second element from the reference location in the vertical direction. In another example, where a level of a first element is described herein to be the same or substantially the same as a level of a second element or “at” the level of the second element, it will be understood that the distance of the first element from the reference location (e.g., the first surface 110a and/or the second surface 110b of the front side redistribution layer 110) in the vertical direction may be the same or substantially the same as the distance of the second element from the reference location in the vertical direction. In some example embodiments, a ‘height’ of an element may refer to a dimension of the element in the vertical direction (e.g., length of the element between opposing top/bottom surfaces of the element in the vertical direction).

The barrier metal layers 180 are interposed at interfaces between the second conductors 140 and a stack 164 of both of the second organic insulating layer 162 and the silicon insulating layer 160. The barrier metal layers 180 may each include titanium (Ti) or a titanium alloy. The barrier metal layers 180 may reduce, minimize, or prevent a metal of the second conductors 140 from diffusing into the second organic insulating layer 162 and the silicon insulating layer 160 to suppress a short circuit between a plurality of wirings. In addition, the barrier metal layers 180 may reduce, minimize, or prevent an oxidation chemical reaction that may occur between the second conductors 140 and the silicon insulating layer 160, and may therefore increase chemical stability between structures of the second redistribution layer 122.

The semiconductor package 100 includes the first semiconductor chip 130. The first semiconductor chip 130 includes the third conductors 150 and the silicon insulating layer 170, where the third conductors 150 are in the silicon insulating layer 170. In some example embodiments, the third conductors 150 may include copper. In some example embodiments, the third conductors 150 may be a metallic material to which hybrid bonding may be applied. In some example embodiments, the silicon insulating layer 170 may include a silicon oxide (e.g., SiO₂). In some example embodiments, the silicon insulating layer 170 may be a silicon nitride, a silicon oxynitride, or another suitable dielectric material. The silicon insulating layer 170 may be referred to interchangeably herein as a second silicon insulating layer.

The organic interposer 120 and the first semiconductor chip 130 may be bonded by (e.g., based on) hybrid bonding. The hybrid bonding is a method of bonding two devices by fusing the same materials of two devices using a bonding property of the same material. Here, the hybrid bonding means that two different types of bondings are made. For example, the hybrid bonding means that two devices are bonded by a first type of metal-to-metal bonding and a second type of non-metal-to-non-metal bonding. The second conductors 140 of the organic interposer 120 may be directly bonded to the third conductors 150 of the first semiconductor chip 130 by metal-metal hybrid bonding. The second conductors 140 may be directly bonded to separate, respective third conductors 150, such that each second conductor 140 is directly bonded to a separate, respective third conductor 150. A metallic bond is formed at interfaces between the second conductors 140 of the organic interposer 120 and the third conductors 150 of the first semiconductor chip 130 by the metal-metal hybrid bonding. The second conductors 140 of the organic interposer 120 and the third conductors 150 of the first semiconductor chip 130 may be made of the same material so that the interfaces between the second conductors 140 of the organic interposer 120 and the third conductors 150 of the first semiconductor chip 130 are lost after the hybrid bonding. The organic interposer 120 and the first semiconductor chip 130 may be electrically connected to each other through the second conductors 140 of the organic interposer 120 and the third conductors 150 of the first semiconductor chip 130.

The silicon insulating layer 160 (also referred to herein as a first silicon insulating layer) of the organic interposer 120 may be directly bonded to the silicon insulating layer 170 (also referred to herein as a second silicon insulating layer) of the first semiconductor chip 130 by non-metal-non-metal hybrid bonding. A covalent bond may be formed at an interface between the silicon insulating layer 160 of the organic interposer 120 and the silicon insulating layer 170 of the first semiconductor chip 130 by non-metal-non-metal hybrid bonding. The silicon insulating layer 160 of the organic interposer 120 and the silicon insulating layer 170 of the first semiconductor chip 130 may be made of the same material (e.g., a particular material) so that after (e.g., subsequent to) the hybrid bonding, the interface 184 between the silicon insulating layer 160 of the organic interposer 120 and the silicon insulating layer 170 of the first semiconductor chip 130 are lost such that the silicon insulating layer 160 of the organic interposer 120 and the silicon insulating layer 170 of the first semiconductor chip 130 merge to become separate portions of a single, unitary piece of the particular material, thereby improving structural stability of the semiconductor package 100 that includes the organic interposer 120 and the first semiconductor chip 130 coupled thereto.

In some example embodiments, the second conductors 140 of the organic interposer 120 may be metal vias or metal pads, and the third conductors 150 of the first semiconductor chip 130 may be metal vias or metal pads. Accordingly, metal-metal hybrid bonding of metal vias, metal pads, metal vias and metal pads, and various other combinations may be performed between the organic interposer 120 and the first semiconductor chip 130.

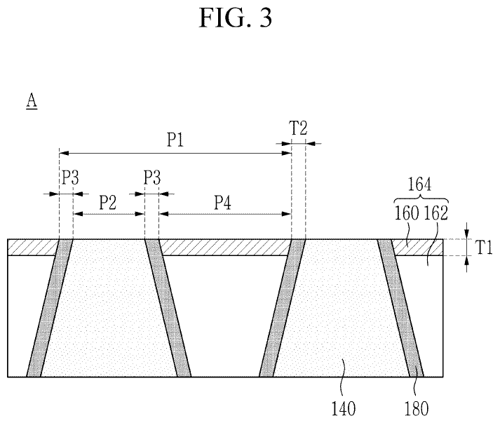

FIG. 3 is a cross-sectional view enlarging an area A of the organic interposer 120 in the cross-sectional view of FIG. 2 according to some example embodiments.

Referring to FIG. 3, the organic interposer 120 includes the second organic insulating layer 162, the silicon insulating layer 160 on the second organic insulating layer 162, the second conductors 140 penetrating through the second organic insulating layer 162 and the silicon insulating layer 160, and the barrier metal layers 180 on sidewalls of the second conductors 140. In some example embodiments, the silicon insulating layer 160 may have a thickness T1 of about 100 nm to about 1000 nm. In some example embodiments, the barrier metal layer 180 may have a thickness T2 of about 10 nm to about 300 nm. In some example embodiments, a pitch that is a sum P1 of a pitch P2 (e.g., cross-sectional thickness) of a cross-section of one second conductor 140 of the second conductors 140, a pitch P3 (e.g., total or cumulative cross-sectional thickness) of a cross-section of the barrier metal layers 180 on the sidewalls of one second conductor 140 of the plurality of second conductors 140, and a pitch P4 (e.g., cross-sectional thickness) of a cross-section of a stack 164 including the second organic insulating layer 162 and the silicon insulating layer 160 on the second organic insulating layer 162 may be 1 μm to 380 μm.

Each second conductor 140 according to the present inventive concepts is illustrated to have a shape in which a width of the conductor becomes narrower from a lower surface of the conductor toward an upper surface of the conductor and each of the silicon insulating layer 160 and the second organic insulating layer 162 according to the present inventive concepts are illustrated to have a shape in which a width of each of them becomes wider from a lower surface of each of them toward an upper surface of each of them. On the contrary, each second conductor 140 may have a shape in which a width of the conductor becomes wider from a lower surface of the conductor toward an upper surface of the conductor and each of the silicon insulating layer 160 and the second organic insulating layer 162 may have a shape in which a width of each of them becomes narrower from a lower surface of each of them toward an upper surface of each of them. In addition, a width between a lower surface of each of the second conductors 140, the silicon insulating layer 160, and the second organic insulating layer 162 and an upper surface each of them may be constant.

By the organic interposer 120 capable of hybrid bonding according to the present inventive concepts, a conductive connection member (e.g., a solder bump, a solder ball, or the like) for electrical coupling between the organic interposer 120 and the first semiconductor chip 130 may not be required and the second conductors 140 of the organic interposer 120 and the third conductors 150 of the first semiconductor chip 130 may be directly bonded.

Since a resistance value between the organic interposer 120 and the first semiconductor chip 130 is reduced by a resistance value of the conductive connection member due to direct bonding between the second conductors 140 of the organic interposer 120 and the third conductors 150 of the first semiconductor chip 130, an overall electrical characteristic of the semiconductor package may be improved.

In addition, since the second conductors 140 of the organic interposer 120 and the third conductors 150 of the first semiconductor chip 130 are directly bonded, a conductive connection member is not required. Further, since the silicon insulation layer 160 of the organic interposer 120 and the silicon insulating layer 170 of the first semiconductor chip 130 are directly bonded, a gap between the organic interposer 120 and the first semiconductor chip 130 may be reduced, minimized, or prevented and the organic interposer 120 and the first semiconductor chip 130 may be integrally formed. Accordingly, structural stability of the semiconductor package may be improved and a more compact semiconductor package may be provided.

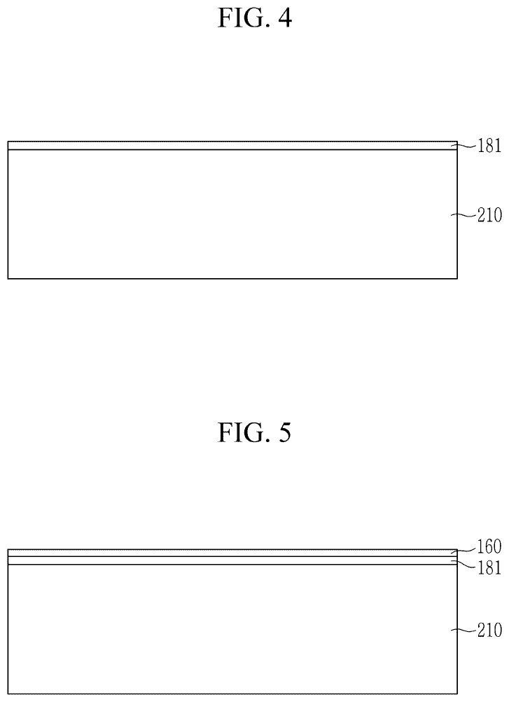

FIGS. 4 to 17 illustrate a series of steps of a semiconductor package manufacturing method according to the present inventive concepts in which the organic interposer 120 capable of metal-to-metal hybrid bonding and non-metal-to-non-metal hybrid bonding is manufactured and then the manufactured organic interposer 120 and the first semiconductor chip 130 are hybrid-bonded.

FIG. 4 is a cross-sectional view illustrating a step of forming a first seed metal layer 181 as one of the steps of a method for manufacturing the semiconductor package according to some example embodiments.

Referring to FIG. 4, the first seed metal layer 181 is formed on a carrier 210. In some example embodiments, for example, the carrier 210 may include a silicon-based material such as glass or silicon oxide, an organic material, or other material such as aluminum oxide, any combination of these materials, or the like. In some example embodiments, a main material (e.g., majority material, entire or substantially entire material, etc.) of the first seed metal layer 181 may include titanium (Ti) or a titanium alloy. In some example embodiments, a physical vapor deposition (PVD) process may be used to deposit the first seed metal layer 181 on the carrier 210. In some example embodiments, a sputtering process may be used to form the first seed metal layer 181 on the carrier 210.

FIG. 5 is a cross-sectional view illustrating a step of forming the silicon insulating layer 160 as one of the steps of a method for manufacturing the semiconductor package according to some example embodiments.

Referring to FIG. 5, the silicon insulating layer 160 (which may be referred to herein interchangeably as a first silicon insulating layer, a second silicon insulating layer, or the like) is formed on the first seed metal layer 181. In some example embodiments, the silicon insulating layer 160 may include a silicon oxide. In some example embodiments, the silicon insulating layer 160 may include SiO₂. In some example embodiments, the silicon insulating layer 160 may be a silicon nitride, a silicon oxynitride, or any other suitable dielectric material. In some example embodiments, the silicon insulating layer 160 may be deposited through chemical vapor deposition (CVD), atomic layer deposition (ALD), plasma-enhanced chemical vapor deposition (PECVD), or any other suitable method. In some example embodiments, after the deposition, the silicon insulating layer 160 may have the thickness T1 of 100 nm to 1000 nm.

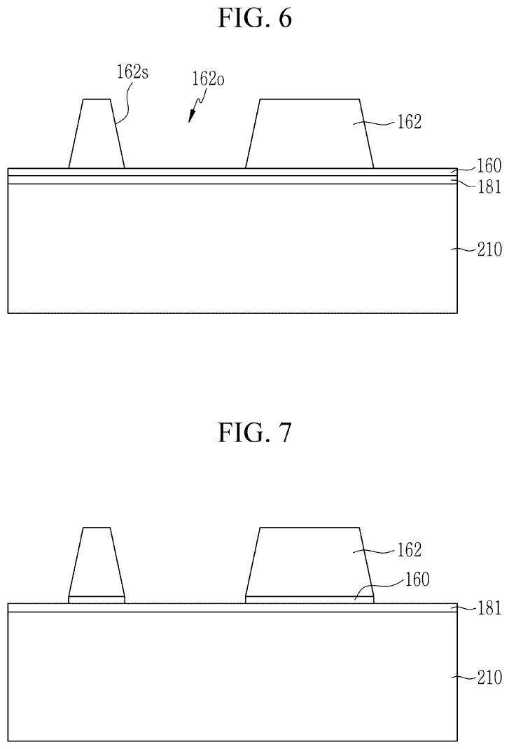

FIG. 6 is a cross-sectional view illustrating a step of forming a patterned second organic insulating layer 162 (which may be referred to herein interchangeably as an organic insulating layer, a first organic insulating layer, or the like) as one of the steps of a method for manufacturing the semiconductor package according to some example embodiments.

Referring to FIG. 6, the second organic insulating layer 162 is formed on the silicon insulating layer 160. In some example embodiments, the second organic insulating layer 162 may be a photosensitive polymer layer. In some example embodiments, the second organic insulating layer 162 may include a photo imageable dielectric (PID) material as a photosensitive polymer. In some example embodiments, the second organic insulating layer 162 may be formed using a lamination method or a coating method. Thereafter, the second organic insulating layer 162 is patterned to have openings 162o (e.g., to have sidewalls 162s defining the plurality of openings 1620) through an exposure step, a development step, and an etching step. After openings are formed at the second organic insulating layer 162, the second organic insulating layer 162 is cured and baked. After curing and baking steps are performed, a film quality of the second organic insulating layer 162 is modified to be harder.

FIG. 7 is a cross-sectional view illustrating a step of removing an exposed silicon insulating layer 160 as one of the steps of a method for manufacturing the semiconductor package according to some example embodiments.

Referring to FIG. 7, the silicon insulating layer 160 (e.g., portions thereof) exposed through the openings 162o of the second organic insulating layer 162 is removed by etching such that at least a portion of the first seed metal layer 181 is exposed. The first seed metal layer 181 may act as an etch stop layer. In addition, in a process of forming and patterning the second organic insulating layer 162 before this step, undesirable scum of the second organic insulating layer 162 may be generated as a by-product. The scum may be removed while the exposed silicon insulating layer 160 is etched. In some example embodiments, the exposed silicon insulating layer 160 and the scum of the second organic insulating layer 162 may be removed by dry etching. In some example embodiments, the exposed silicon insulating layer 160 and scum of the second organic insulating layer 162 may be removed by plasma etching, sputter etching, or ion etching.

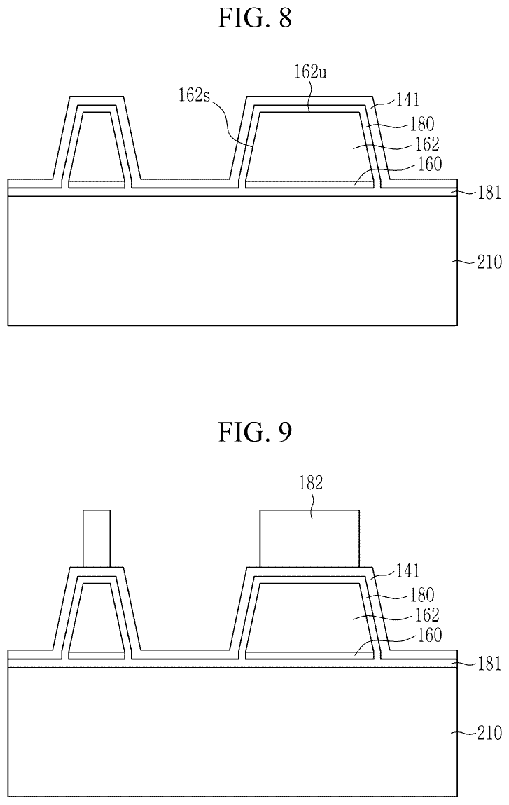

FIG. 8 is a cross-sectional view illustrating a step of forming the barrier metal layer 180 and a second seed metal layer 141 as one of the steps of a method for manufacturing the semiconductor package according to some example embodiments.

Referring to FIG. 8, the barrier metal layer 180 is formed on the second organic insulating layer 162 (e.g., an upper surface 162u and sidewalls 162s thereof). In some example embodiments, a main material of the barrier metal layer 180 may include titanium (Ti) or a titanium alloy. Since titanium or a titanium alloy is a material that is difficult to diffuse into the organic insulating layer, it reduces, minimizes, or prevents diffusion of a metal of the conductor into the organic insulating layer. In some example embodiments, a PVD process may be used to form the barrier metal layer 180. In some example embodiments, a sputtering process may be used to form the barrier metal layer 180. In some example embodiments, the barrier metal layer 180 may have a thickness T2 of 10 nm to 300 nm. In some example embodiments, the barrier metal layer 180 may have an approximately uniform thickness. The barrier metal layer 180 may prevent an oxidation chemical reaction that may occur between the stack of the second organic insulating layer 162 and the silicon insulating layer 160 and the second conductors 140, and may increase chemical stability between structures.

Next, the second seed metal layer 141 is formed on both the first seed metal layer 181 (e.g., exposed portions thereof that are exposed from the second organic insulating layer 162 and the barrier metal layer 180) and the barrier metal layer 180. In some example embodiments, the second seed metal layer 141 may include copper. In some example embodiments, the second seed metal layer 141 is formed by electroless plating. In some example embodiments, a cleaning process or a metal catalyst activation pretreatment process may be performed prior to the electroless plating. In some example embodiments, the second seed metal layer 141 is formed by sputtering. In some example embodiments, the second seed metal layer 141 may have a thickness of about 30 nm to about 1500 nm.

FIG. 9 is a cross-sectional view illustrating a step of forming a patterned photoresist 182 as one of the steps of a method for manufacturing the semiconductor package according to some example embodiments.

Referring to FIG. 9, a photoresist 182 having a particular (or, alternatively, predetermined) thickness is formed on a surface of the second seed metal layer 141 above an upper surface of the second organic insulating layer 162. In some example embodiments, the photoresist 182 may include a dry film Photoresist (DFR). The dry film photoresist (DFR) may be formed by a lamination process. Then, a photomask (not shown) is aligned on an upper portion of the photoresist 182, and the photoresist 182 is exposed and developed. The photoresist 182 includes openings for forming the second conductors 140.

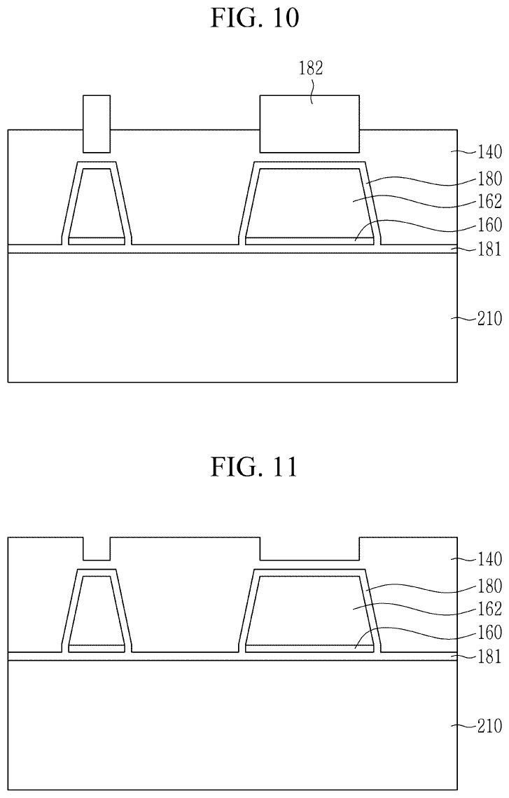

FIG. 10 is a cross-sectional view illustrating a step of forming the second conductors 140 (which may be interchangeably referred to as first conductors) at openings of the photoresist 182 as one of the steps of a method for manufacturing the semiconductor package according to some example embodiments.

Referring to FIG. 10, the second conductors 140 are formed in the openings of the photoresist 182 and thereby formed on the second seed metal layer 141 in the plurality of openings 162o of the second organic insulating layer 162.

In some example embodiments, the second conductors 140 may include copper. In some example embodiments, the second conductors 140 may be a metallic material to which hybrid bonding may be applied. In some example embodiments, the second conductors 140 are formed by electroplating. The second conductors 140 are formed by growing a metal film by the electroplating from the previously formed second seed metal layer 141. In some example embodiments, after the second conductors 140 are formed, an annealing process may be performed.

FIG. 11 is a cross-sectional view illustrating a step of removing the photoresist 182 as one of the steps of a method for manufacturing the semiconductor package according to some example embodiments.

Referring to FIG. 11, the photoresist 182 is stripped. After the photoresist 182 is stripped, the second seed metal layer 141 above an upper surface of the second organic insulating layer 162 is exposed. In FIG. 11, a configuration below an exposed surface after the photoresist 182 is stripped corresponds to the second seed metal layer 141, but the second seed metal layer 141 is not separately marked to show that the second seed metal layer 141 is continuously formed with the second conductors 140.

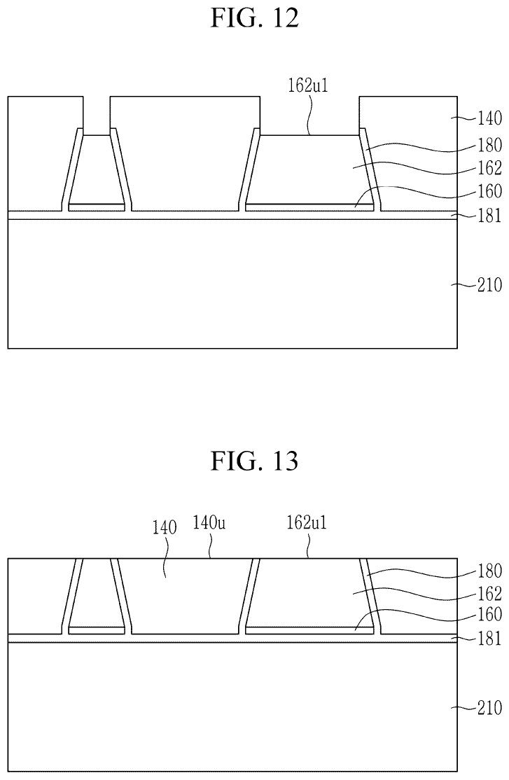

FIG. 12 is a cross-sectional view illustrating a step of removing both the barrier metal layer 180 and the second seed metal layer 141 as one of the steps of a method for manufacturing the semiconductor package according to some example embodiments.

Referring to FIG. 12, an exposed second seed metal layer 141 and the barrier metal layer 180 below the exposed second seed metal layer 141 are removed by etching, and an upper surface 162u1 of the second organic insulating layer 162 is exposed. Restated, both the barrier metal layer 180 and the second seed metal layer 141 above the upper surface 162u1 of the second organic insulating layer 162 are removed.

FIG. 13 is a cross-sectional view illustrating a step of performing a chemical mechanical polishing (CMP) process as one of the steps of a method for manufacturing the semiconductor package according to some example embodiments.

Referring to FIG. 13, the CMP process is performed to match levels of the second conductors 140 and the second organic insulating layer 162, for example such that respective surfaces 140u and 162u1 of the second conductors 140 and the second organic insulating layer 162 are coplanar or substantially coplanar. In some example embodiments, the CMP process may be performed after the second organic insulating layer 162 is additionally formed on an upper surface of an exposed second organic insulating layer 162.

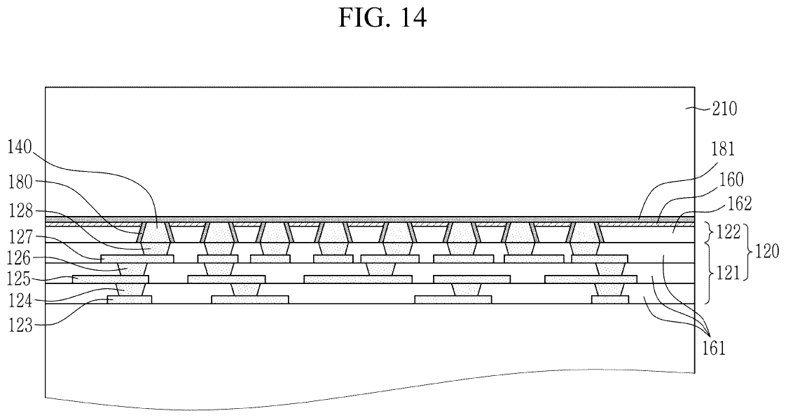

FIG. 14 is a cross-sectional view illustrating a step of forming the first redistribution layer 121 (also referred to herein as a redistribution layer) of the organic interposer 120 as one of the steps of a method for manufacturing the semiconductor package according to some example embodiments. For convenience of description, illustrations of the second semiconductor chip 131, the through via 132, the molding material 133, and the configuration below the molding material in FIG. 2 are omitted in FIGS. 14 to 17.

Referring to FIG. 14, the first redistribution layer 121 is formed on the second redistribution layer 122 (e.g., on both the surface 162u1 of the second organic insulating layer 162 and the surface 140u of the second conductors 140). First, the redistribution via 128 is formed on the second redistribution layer 122 to be electrically coupled to the second redistribution layer 122. The redistribution via 128 may be formed by using a photoresist etching process or a hard mask etching process. In some example embodiments, the redistribution via 128 may be formed of pure copper, a copper-containing composition, or a copper alloy. In some example embodiments, the redistribution via 128 may be formed of another material such as nickel, aluminum, titanium, or an alloy of nickel, aluminum, and titanium. In some example embodiments, the redistribution via 128 may be deposited using a PVD process.

Next, the first organic insulating layer 161 is formed to match a level of (e.g., have a surface that is coplanar with a corresponding surface of) the redistribution via 128. The first organic insulating layer 161 may be a photosensitive polymer layer. The photosensitive polymer may include a photo imageable dielectric (PID) material. In some example embodiments, the PID may include a polyimide-based photosensitive polymer, a novolac-based photosensitive polymer, polybenzoxazole, a silicone-based polymer, an acrylate-based polymer, or an epoxy-based polymer. In some example embodiments, the first organic insulating layer 161 may be deposited through CVD, ALD, PECVD, or another method.

Next, a CMP process or a mechanical grinding process is applied to planarize upper surfaces of the redistribution via 128 and the first organic insulating layer 161.

Thereafter, the redistribution lines 123, 125, and 127, the redistribution vias 124 and 126, and the first organic insulating layer 161 for molding the redistribution lines 123, 125, and 127 and the redistribution vias 124 and 126 therein may be formed by applying the same process of forming the redistribution via 128 and the first organic insulating layer 161 for molding the redistribution via 128 therein.

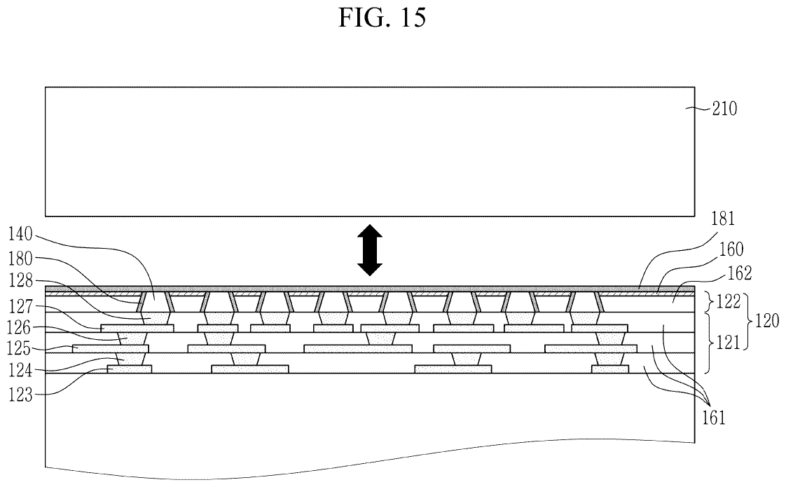

FIG. 15 is a cross-sectional view illustrating a step of removing the carrier 210 as one of by the steps of a method for manufacturing the semiconductor package according to some example embodiments.

Referring to FIG. 15, after the organic interposer 120 is manufactured, the carrier 210 is debonded from the organic interposer 120. After the carrier 210 is debonded, the first seed metal layer 181 is exposed.

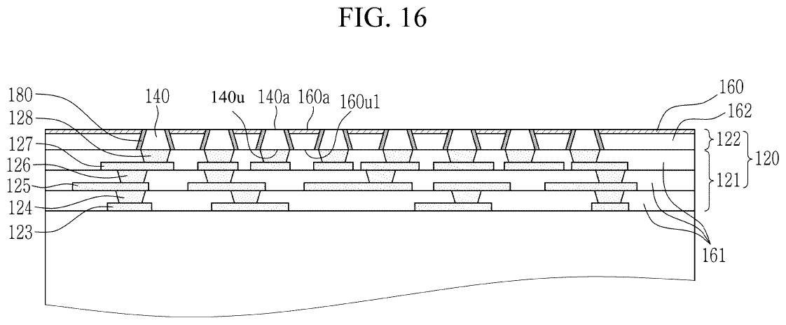

FIG. 16 is a cross-sectional view illustrating a step of removing the first seed metal layer 181 as one of the steps of a method for manufacturing the semiconductor package according to some example embodiments.

Referring to FIG. 16, the first seed metal layer 181 is removed by etching, thereby exposing the second conductors 140 and the silicon insulating layer 160. In the conventional hybrid bonding, since a bonding surface of a structure has to have surface roughness of 100 nm or less (e.g., 0.1 nm to 100 nm) in order for the hybrid bonding to be easily performed, a CMP process has to be performed before (e.g., prior to) the hybrid bonding to obtain such a minimum surface roughness. However, according to the present inventive concepts, when the first seed metal layer 181 is removed, an upper surface 160a of the silicon insulating layer 160 and an upper surface 140a of each of the second conductors 140, which are bonding surfaces and may be the respective uppermost surfaces of the silicon insulating layer 160 and the second conductors 140, have the same or substantially the same level (e.g., have respective levels that are at the same or substantially the same level, are coplanar or substantially coplanar) so that the CMP process that has to be performed before the hybrid bonding in a conventional hybrid bonding process may be omitted in a method according to some example embodiments, thereby simplifying the method for manufacturing the semiconductor package and therefore reducing manufacturing costs and improving manufacturing efficiency and further improving the reliability of manufactured semiconductor packages by virtue of reducing the likelihood of manufacturing defects that might occur as a result of the CMP process (e.g., incorrect and/or incomplete CMP process resulting in bonding surfaces having insufficiently reduced surface roughness to enable proper conventional hybrid bonding (e.g., surface roughness of more than 100 nm).

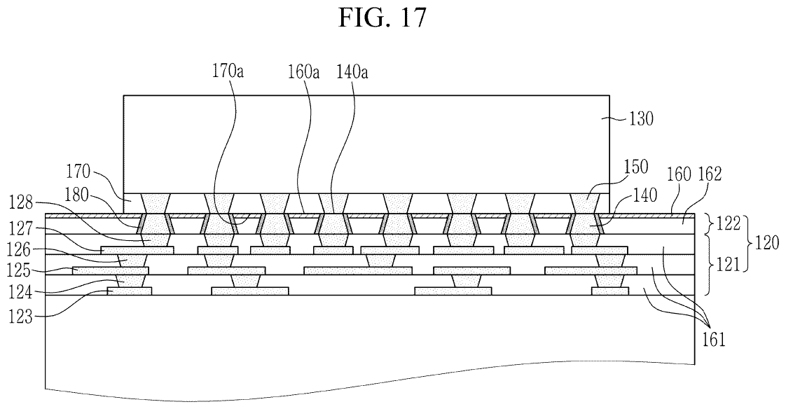

FIG. 17 is a cross-sectional view illustrating a step of hybrid-bonding the organic interposer 120 and the first semiconductor chip 130 as one of the steps of a method for manufacturing the semiconductor package according to some example embodiments.

Referring to FIG. 17, first, bonding surfaces of the second conductors 140 and the silicon insulating layer 160 in the organic interposer 120, and the third conductors 150, and the silicon insulating layer 170 in the first semiconductor chip 130 are cleaned. In some example embodiments, cleaning of the bonding surfaces may be performed by wet cleaning. Next, bonding surfaces of the silicon insulating layer 160 of the organic interposer 120 and the silicon insulating layer 170 of the first semiconductor chip 130 (e.g., respective surfaces 160a and 170a) are activated. In some example embodiments, each bonding surface may be surface treated by plasma activation. Then, the organic interposer 120 and the first semiconductor chip 130 are aligned (e.g., overlapped in a vertical direction) for hybrid bonding. Then, the activated bonding surface of the silicon insulating layer 160 of the organic interposer 120 (e.g., upper surface 160a) and the activated bonding surface of the silicon insulating layer 170 of the first semiconductor chip 130 (e.g., surface 170a) contact each other to be pre-bonded.

Thereafter, the organic interposer 120 and the first semiconductor chip 130 are hybrid-bonded. First, the silicon insulating layer 160 of the organic interposer 120 and the silicon insulating layer 170 of the first semiconductor chip 130 are bonded by treatment. The treatment strengthens bonding between the pre-bonded silicon insulating layer 160 of the organic interposer 120 and the pre-bonded silicon insulating layer 170 of the first semiconductor chip 130. In some example embodiments, the treatment may be performed at a temperature ranging from about 100° C. to about 150° C.

Then, the second conductors 140 of the organic interposer 120 and the third conductors 150 of the first semiconductor chip 130 are bonded by annealing. For example, each second conductor 140 may be bonded to a separate, respective third conductor 150. It will be understood that the third conductors 150 may be interchangeably referred to herein as second conductors, first conductors, conductors, or the like. In some example embodiments, a pressure (e.g., ambient pressure) during the annealing may be less than about 30 MPa (e.g., about 1 MPa to about 30 MPa). In some example embodiments, the annealing may be performed at a temperature (e.g., ambient temperature) of about 100° C. to 500° C. In some example embodiments, the annealing may be performed at a temperature ranging from about 300° C. to about 400° C. In some example embodiments, the hybrid bonding may be performed in an inert environment such as an environment (e.g., ambient environment) filled with an inert gas comprising N2, Ar, He, or a combination of N2, Ar, and He.

While the inventive concepts have been described in connection with what is presently considered to be practical example embodiments, it is to be understood that the inventive concepts are not limited to such example embodiments, but, on the contrary, are intended to cover various modifications and equivalent arrangements included within the spirit and scope of the appended claims.

What is claimed is:

1. A semiconductor package, comprising:
an interposer including a first redistribution layer and a second redistribution layer that is on the first redistribution layer and is electrically coupled to the first redistribution layer; and
a semiconductor chip on the interposer,
wherein the first redistribution layer includes a first organic insulating layer and a plurality of first conductors in the first organic insulating layer,
wherein the second redistribution layer includes a second organic insulating layer, a first silicon insulating layer on the second organic insulating layer, and a plurality of second conductors penetrating through both of the second organic insulating layer and the first silicon insulating layer,
wherein the semiconductor chip includes a second silicon insulating layer and a plurality of third conductors in the second silicon insulating layer, and
wherein each second conductor of the plurality of second conductors is directly bonded to a separate, respective third conductor of the plurality of third conductors, and
wherein the first silicon insulating layer is directly bonded to the second silicon insulating layer.

2. The semiconductor package of claim 1, wherein a level of an uppermost surface of the plurality of second conductors and a level of an uppermost surface of the first silicon insulating layer are substantially a same level.

3. The semiconductor package of claim 1, wherein both of the first silicon insulating layer and the second silicon insulating layer include a silicon oxide.

4. The semiconductor package of claim 1, wherein both of the plurality of second conductors and the plurality of third conductors include copper (Cu).

5. The semiconductor package of claim 1, wherein the interposer comprises an organic interposer.

6. The semiconductor package of claim 1, wherein each of the first organic insulating layer and the second organic insulating layer includes a photo imageable dielectric (PID).

7. The semiconductor package of claim 1, wherein
the second redistribution layer further includes barrier metal layers, and
the barrier metal layers are interposed between the plurality of second conductors and a stack that includes both of the second organic insulating layer and the first silicon insulating layer.

8. The semiconductor package of claim 7, wherein each barrier metal layer of the barrier metal layers includes titanium (Ti).

9. A semiconductor package, comprising:
an interposer that includes a first redistribution layer and a second redistribution layer on the first redistribution layer; and
a semiconductor chip on the interposer,
wherein the first redistribution layer includes
a first organic insulator layer, and
a plurality of first conductors that include redistribution lines and redistribution vias in the first organic insulating layer,
wherein the second redistribution layer includes
a second organic insulator layer,
a first silicon insulating layer on the second organic insulating layer,
a plurality of second conductors that penetrate through both of the second organic insulating layer and the first silicon insulating layer, the plurality of second conductors electrically coupling the first redistribution layer and the semiconductor chip, wherein a level of an uppermost surface of the plurality of second conductors and a level of an uppermost surface of the first silicon insulating layer are substantially a same level, and
barrier metal layers that are interposed at interfaces between the plurality of second conductors and a stack that includes both of the second organic insulating layer and the first silicon insulating layer,
wherein the semiconductor chip includes a plurality of third conductors and a second silicon insulating layer, and
wherein each second conductor of the plurality of second conductors is directly bonded to a separate, respective third conductor of the plurality of third conductors and the first silicon insulating layer is directly bonded to the second silicon insulating layer.

10. The semiconductor package of claim 9, wherein the first silicon insulating layer has a thickness of about 100 nm to about 1000 nm.

11. The semiconductor package of claim 9, wherein each barrier metal layer of the barrier metal layers has a thickness of about 10 nm to about 300 nm.

12. The semiconductor package of claim 9, wherein a sum of a pitch of a cross-section of one second conductor of the plurality of second conductors, a pitch of a cross-section of the barrier metal layers on sidewalls of the one second conductor, and a pitch of a cross-section of the stack is about 1 μm to about 380 μm.

13. A method for manufacturing a semiconductor package, the method comprising:
forming a first silicon insulating layer on a first seed metal layer;
forming an organic insulating layer including a plurality of openings to expose the first silicon insulating layer;
removing the exposed first silicon insulating layer to expose the first seed metal layer;
forming a barrier metal layer on an upper surface and sidewalls of the organic insulating layer;
forming a second seed metal layer on both of the first seed metal layer and the barrier metal layer;
forming a plurality of first conductors on the second seed metal layer in the plurality of openings of the organic insulating layer;
removing both of the barrier metal layer and the second seed metal layer above the upper surface of the organic insulating layer;
forming a redistribution layer on both of the upper surface of the organic insulating layer and an upper surface of the first conductors;
removing the first seed metal layer to expose the plurality of first conductors and the first silicon insulating layer; and
bonding each first conductor of the plurality of first conductors to a separate, respective second conductor of a plurality of second conductors of a semiconductor chip, and bonding the first silicon insulating layer to a second silicon insulating layer of the semiconductor chip.

14. The method of claim 13, wherein the removing of the exposed first silicon insulating layer includes removing scum of the organic insulating layer.

15. The method of claim 13, wherein
the first seed metal layer and the barrier metal layer include titanium (Ti), the second seed metal layer and the plurality of first conductors include copper (Cu), and
wherein the second seed metal layer has a thickness of about 30 nm to about 1500 nm.

16. The method of claim 13, wherein the forming of the second seed metal layer includes performing sputtering or electroless plating.

17. The method of claim 13, wherein the forming of the plurality of first conductors includes performing electroplating.

18. The method of claim 13, wherein in the removing of the first seed metal layer, an uppermost surface of the plurality of first conductors and an uppermost surface of the first silicon insulating layer are at substantially a same level without performing a chemical mechanical polishing (CMP) process.

19. The method of claim 13, wherein the bonding each of the plurality of first conductors to each of the plurality of second conductors of the semiconductor chip includes annealing at a temperature of about 100° C. to about 500° C. and a pressure of less than about 30 MPa.

20. The method of claim 13, wherein before the forming of the plurality of first conductors, a photoresist is formed on the second seed metal layer above the upper surface of the organic insulating layer.
